(19) United States
(12) Patent Application Publication
(10) Pub. No.: US 2006/0145355 A1
(43) Pub. Date: Jul. 6, 2006

(54) Plug filling without step-height difference for dual damascene process

(75) Inventor: Jen-Chieh Shih, Yongkang City (TW)

Correspondence Address: HAYNES AND BOONE, LLP, 901 MAIN STREET, SUITE 3100, DALLAS, TX, 75202, US

(73) Assignee: Taiwan Semiconductor Manufacturing Company, Ltd., Hsin-Chu (TW)

(21) Appl. No.: 11/028,931

(22) Filed: Jan. 4, 2005

(51) Int. Cl. H01L 21/4763

(52) U.S. Cl. 257/774; 438/638

(57) ABSTRACT

A method for manufacturing a dual damascene structure on a semiconductor substrate is provided. The method includes forming an insulator above the substrate and patterning the insulator to include a plurality of plug openings. A plug-filler material is used for filling one or more of the plug openings and extending above the insulator. A portion of the plug-filler material extending above the insulator can be removed by using a reduced resist coating (RRC) solvent.

### BACKGROUND

The present invention relates to the fabrication of substrates such as semiconductor wafers, and more specifically, to filling plugs such as vias or contacts in a dual damascene process.

Semiconductor device geometries have dramatically decreased in size since such devices were first introduced several decades ago. Since then, integrated circuits have generally followed the two year/half-size rule (often called Moore's Law), which means that the number of devices on a chip doubles every two years. Today's fabrication plants are routinely producing devices having 0.13 micron and even 90 nm feature sizes.

Metallization of integrated circuits can employ a process known as damascene, in which a substrate is inlaid with metal. Damascene and a related process known as dual damascene (both referred to henceforth as “damascene”) have become widely used in integrated circuit manufacturing for devices with geometries of 0.1 micron or less. Generally, the damascene process involves creating interconnect schemes by forming plug openings and/or cutting trenches in a dielectric, and then filling those openings and/or trenches with metal. Any excess metal is then removed. Damascene methods often use tungsten or copper as the bulk filling interconnect metal because of its low resistance. A copper interconnect is frequently surrounded with a metal barrier.

It is desired that fabrication processes, such as dual damascene processes, be performed with as few steps as possible. Reducing and/or eliminating steps not only speeds up the overall process time, but also may reduce fabrication costs and reduced the amount of defects due to the reduced handling of the wafers.

### BRIEF DESCRIPTION OF THE DRAWINGS

Aspects of the present disclosure are best understood from the following detailed description when read with the accompanying figures. It is emphasized that, in accordance with the standard practice in the industry, various features may not be drawn to scale. In fact, the dimensions of the various features may be arbitrarily increased or reduced for clarity of discussion.

FIG. 1 is a flowchart of a processing method for performing one embodiment of the present invention.

FIGS. 2-5 are cross sectional views of an integrated circuit being processed according to the method of FIG. 1.

FIG. 6 is a chemical diagram of an example Novolac resin that can be used in one or more embodiments of the present invention.

FIG. 7 is a chemical diagram of an example PHS polymer that can be used in one or more embodiments of the present invention.

### DETAILED DESCRIPTION

The present disclosure provides a new method for filling plug openings on a semiconductor substrate, such as can be used in a dual damascene process. The present disclosure also provides a unique plug-filling material for fabricating integrated circuits. It is understood, however, that the specific examples provided in the present disclosure are meant to teach the broader inventive concept, and one of ordinary skill in the art can easily apply the teachings of the present disclosure to other processes, devices and material. In addition, the present disclosure may repeat reference numerals and/or letters in the various examples. This repetition is for the purpose of simplicity and clarity and does not in itself dictate a relationship between the various embodiments and/or configurations discussed. Moreover, the formation of a first feature over or on a second feature in the description that follows may include embodiments in which the first and second features are formed in direct contact, and may also include embodiments in which additional features may be formed interposing the first and second features, such that the first and second features may not be in direct contact.

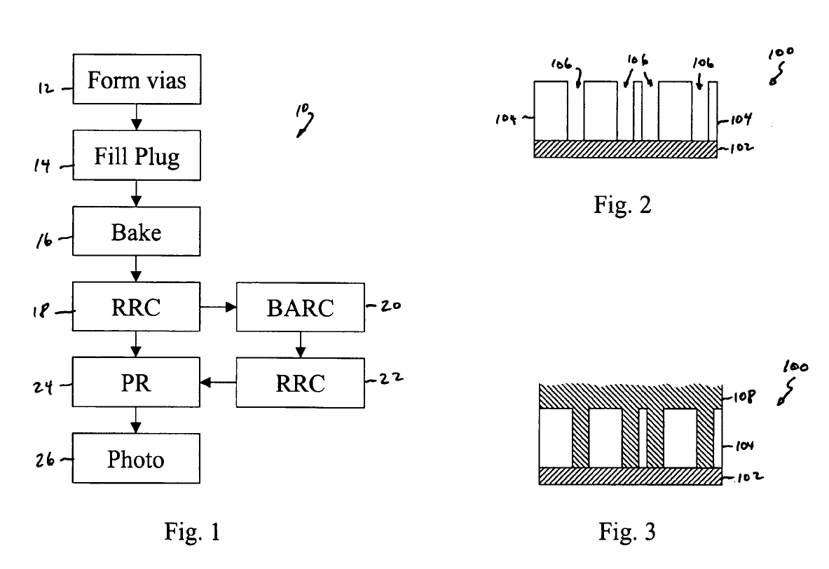

Referring now to FIG. 1, a method 10 can be used to process an integrated circuit device in one or more stages of overall device fabrication. For the sake of example, an integrated circuit 100 of FIGS. 2-5 will be discussed in intermediate stages of fabrication according to the steps of FIG. 1. Execution of the method 10 begins at step 12, where one or more via plugs are formed.

Referring also to FIG. 2, for the sake of example, the method 10 will be used to fabricate copper damascene interconnects. This can be performed on the integrated circuit 100 which is currently at a back-end stage of processing. The integrated circuit 100 may include a plurality of MOSFETs and/or other integrated circuit devices collectively illustrated as a layer 102. In the present embodiment, these devices 102 are covered with an insulator layer 104, such as phosphosilicate glass (PSG). The insulator 104 layer may also be borophosphosilicate glass (BPSG) that can reduce sodium or other contaminates from penetrating down to the devices 102 and can provide global planarization over the devices. Alternatively or in addition, the insulator layer 24 can include a low-k dielectric. The insulator layer 104 can be formed by chemical vapor deposition (CVD), plasma enhanced chemical vapor deposition (PECVD), atomic laver deposition (ALD), or any other method that is known by one who is skilled in the art. It is understood that many types and quantities of layers 104 can be used.

According to step 12, one or more via plug openings 106 are created in the insulator layer 104 by a plasma etch or another fabrication method known to those skilled in the art. In some embodiments, the via plug openings 106 can be lined with a metal barrier such as Ti, TiN, Ta, TaN, or other appropriate material.

Referring now to FIGS. 1 and 3, at step 14, the via plug openings 106 are filled with a plug-filler material to form a layer 108. The plug-filler material can include tungsten, copper, or some other cross-linking material. As can be seen, the plug-filler material extends above a top surface of the insulator layer 104. The composition of the plug-filler material will be discussed in greater detail below.

At step 16, the integrated circuit 100 is subjected to a bake process for curing the plug-filler material. Baking is a well-known conventional process and depends on various parameters that may change from one design to the next. The integrated circuit is then sent directly to a metal trench/photolithography process, not requiring any intermediate etch removal of excessive plug-filler material form the top surface of layer 108.

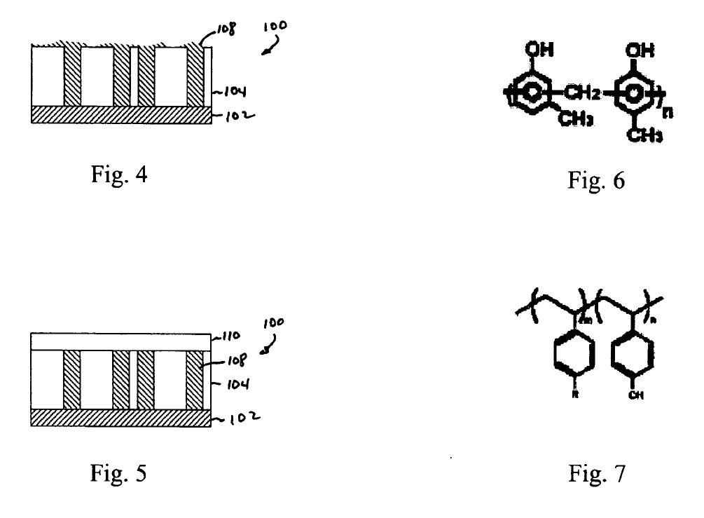

Referring now to FIGS. 1 and 4, at step 18 of the metal trench/photolithography process, the integrated circuit 100 is subjected to a reduced resist coating (RRC) process to rinse the surface of the layer 108. Although the RRC process may be a conventional process that provides a solvent to help reduce the consumption of photoresist, in the present embodiment the RRC solvent removes a significant portion of the plug-filler material, such as more than 200 Angstroms of material thickness. This is due to the unique composition of the plug-filler material, discussed in greater detail below. As a result, the thickness of the material is reduced.

At step 20, a bottom-side antireflective coating (BARC) can be applied, if desired. For example, some 0.13 micron processes may not use BARC, while some 90nm process may require BARC. At step 20, if BARC is applied, a second RRC process can be used to rinse the surface of the integrated circuit 100.

Referring to FIGS. 1 and 5, at step 24, a layer of photoresist 110 is applied to the top surface of the integrated circuit 100. Although not shown, additional steps can be performed throughout the method 10. For example, after the photoresist 110 is applied, additional processing steps can be performed, such as exposing the photoresist 110 to form a trench pattern, applying the etching process to form the trench pattern on the insulator 104, removing the plug-filler material, filling the patterned trenches with conductive material, and so forth.

Plug-Filler Material

In the present embodiments, the cross-linking action of the plug filler material for layer 108 is modified so that it is more soluble to an otherwise-conventional RRC solvent. In the present embodiment, the plug-filler material includes a cross-linking material and an additive. The plug-filler material can be selected for various properties beyond the scope of the present disclosure.

Table 1 below describes five different additives for the plug material. This list is not intended to be exhaustive, but is intended to provide several different examples. Novolac, which is graphically illustrated in FIG. 6, refers to a specific type of epoxy resin. PHS, or poly hydroxy styrene, which is graphically illustrated in FIG. 7, refers to a polymer. The Novalac and PHS are provided with different molecular weights (Mw, approximate) for each additive sample (No.), at a predetermined deposition temperature (Td). The Novolac and PHS materials serve to reduce cross-linking in the plug-filler material, thereby making it easier to be removed at RRC.

TABLE 1

| No. | Material | Mw | Td (° C.) |
|---|---|---|---|
| 1 | Novolac | 3,000 | 170 |
| 2 | Novolac | 5,400 | 201 |
| 3 | Novolac | 1,800 | 353 |
| 4 | PHS | 2,800 | 371 |
| 5 | PHS | 3,800 | ND |

To illustrate by example, different percentages of each of the above-listed additives were combined with cross-linking material to form the plug-filler material, and the results are provided in Table 2, below. The columns A-K represent different experiments, with the column K representing a baseline where no additives are provided. The row “Sample No.” refers to the with the cross-linking material. The row “Thickness” identifies the thickness, in Angstroms, of the plug-filler material after step 16 of method 10 (FIGS. 1 and 3). The row labeled “After RRC” identifies a thickness, in Angstroms, of the plug-filler material after step 18 of the method 10 (FIGS. 1 and 4). The rows labeled “Range” describe a variance in the thickness for the immediately-above listed rows.

TABLE 2.1

| | A | B | C | D | E |
|---|---|---|---|---|---|
| Sample No. | 1 | 2 | 3 | 4 | 5 |
| Percent | 50 | 50 | 50 | 50 | 50 |
| Thickness | 933.7 | 921.0 | 920.3 | 914.4 | 908.5 |
| Range | 13.5 | 10.2 | 10.7 | 8.0 | 10.3 |
| After RRC | 713.0 | 920.0 | 811.0 | 909.0 | 908.0 |
| Range | 20.5 | 5.7 | 25.5 | 7.7 | 9.8 |
| Removed | 220.7 | 1.0 | 109.3 | 5.4 | 0.5 |

TABLE 2.2

| | F | G | H | I | J | K |
|---|---|---|---|---|---|---|
| Sample No. | 1 | 2 | 3 | 4 | 5 | — |
| Percent | 25 | 25 | 25 | 25 | 25 | 100 |
| Thickness | 911.7 | 904.6 | 923.0 | 925.9 | 919.5 | 887.1 |
| Range | 29.1 | 10.5 | 7.9 | 13.2 | 10.9 | 8.9 |
| After RRC | 40.3 | 704.0 | 134.0 | 564.0 | 772.0 | 887.0 |
| Range | 11.8 | 26.0 | 200.0 | 45.6 | 23.0 | 8.9 |
| Removed | 871.4 | 200.6 | 789.0 | 361.9 | 147.5 | 0.1 |

Column K of Table 2 represents a baseline procedure in which no additive (e.g., no PHS or Novolac) is used in the plug-filler material. As a result, a layer 108 of about 887.1 Angstroms in thickness, with a range of 8.9 Angstroms is formed at steps 14 and 16 of the method 10 (FIGS. 1 and 3). Going directly from the bake step 16 to the RRC step 18, the RRC solvent removed practically none of the plug-filler material (0.1 Angstroms), leaving a final “After RRC” thickness of 887.0 Angstroms with a range of 8.9 Angstroms. For the sake of further example, it is desired to have a final “After RRC” thickness of about 500-800 Angstroms. Therefore, the baseline mixture of column K is not acceptable for the present example.

Referring now to column A of Table 2, a mixture of 50% conductive material and 50% Novolac (Mw of 3000) produced a layer 108 (FIG. 3) of about 933.7 Angstroms in thickness, with a range of 13.5 Angstroms. Going directly from the bake step 16 (FIG. 1) to the RRC step 18, the RRC solvent removed 220.7 Angstroms, leaving a final “After RRC” thickness of 713.0 Angstroms with a range of 20.5 Angstroms. In furtherance of the previous example, this mixture of 50% conductive material and 50% Novolac (Mw of 3000) produces a final “After RRC” thickness in the desired range of about 500-800 Angstroms. Therefore, the mixture of column A is acceptable for this example of desired thickness.

Referring now to column F of Table 2, a mixture of 75% conductive material and 25% Novolac (Mw of 3000) produced a layer 108 (FIG. 3) of about 911.7 Angstroms in thickness, with a range of 29.1 Angstroms. Going directly from the bake step 16 (FIG. 1) to the RRC step 18, the RRC solvent removed 871.4 Angstroms, leaving a final “After RRC” thickness of 40.3 Angstroms with a range of 11.8 Angstroms. In furtherance of the present example, this mixture of 75% conductive material and 25% Novolac (Mw of 3000) does not produce a final “After RRC” thickness in the desired range of about 500-800 Angstroms. Therefore, the mixture of column F is not acceptable for this example range of desired thickness.

With the given experimental results of Table 2 and the present example range of about 500-800 Angstroms thickness for the layer, it can be seen that columns A, C, G, I, and J represent acceptable mixtures of cross-linking material and additive. It can also be seen that a desired thickness, concentration, or viscosity can be further “fine tuned” by changing the mixture concentrations of the additive or other parameters. Furthermore, the above-described experimental results were created using conventional RRC solvent, and in other embodiments, this solvent can be modified to further facilitate obtaining a desired thickness.

In summary, the present embodiment provides a novel dual damascene semiconductor device including a substrate and an insulator above the substrate including a plurality of openings filled with a plug-filler material. The plug-filler material includes a cross-linking material and an additive, the additive selected and provided in a concentration by which a significant portion of the plug-filler material can be removed during a reduced resist coating (RRC) process. The thickness of the plug-filling material can be measured by using optical critical dimension (OCD) measurement to check the thickness before RRC and after RRC without destroying the wafer.

In another embodiment, a method is provided for manufacturing a dual damascene structure on a semiconductor substrate. The method includes forming an insulator above the substrate and patterning the insulator to include a plurality of plug openings. Plug-filler material fills one or more of the plug openings and extends above the insulator. A portion of the plug-filler material extending above the insulator can then be removed by using a solvent.

In another embodiment, a plug-filling material for use in a dual damascene structure on a semiconductor substrate is provided. The plug-filling material includes at least fifty percent concentration of cross-linking material and at least twenty five percent concentration of an additive. The additive reduces a cross-linking property of the plug-filling material so that a substantial portion of the plug-filling material can be removed, after baking, by using an RRC solvent.

The foregoing has outlined features of several embodiments according to aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions and alterations herein without departing from the spirit and scope of the present disclosure.

What is claimed is:

1. A dual damascene semiconductor device, comprising:
a substrate;
an insulator above the substrate, the insulator including a plurality of openings;
a filler material for filling one or more openings of the insulator, the filler material including a cross-linking material and an additive, the additive selected and provided in a concentration by which a significant portion of the filler material can be removed during a reduced resist coating (RRC) process.

2. The semiconductor device of claim 1 wherein the additive includes Novolac.

3. The semiconductor device of claim 1 wherein the additive includes poly hydroxy styrene (PHS).

4. The semiconductor device of claim 1 wherein the additive is of a composition that effectively reduces a cross-linking characteristic of the cross-linking material.

5. The semiconductor device of claim 1 wherein the selected portion is between about 400-800 Angstroms of the filler material.

6. The semiconductor device of claim 1 wherein a ratio of additive and cross-linking material is about 1:1.

7. The semiconductor device of claim 1 wherein a ratio of additive and cross-linking material is about 1:3.

8. A method for manufacturing a dual damascene structure on a semiconductor substrate, comprising:
forming an insulator above the substrate;
patterning the insulator to include a plurality of plug openings;
providing a plug-filler material for filling one or more of the plug openings and extending above the insulator; and
removing a portion of the plug-filler material extending above the insulator by using a solvent.

9. The method of claim 8 wherein the plug filler includes Novolac.

10. The method of claim 8 wherein the plug filler includes poly hydroxy styrene (PHS).

11. The method of claim 8 wherein the plug filler includes a conductive material and an additive that effectively reduces a cross-linking characteristic of the conductive material.

12. The method of claim 8 wherein the portion is between about 400-8000 Angstroms in thickness.

13. The method of claim 8 further comprising:
applying a layer of photoresist after the portion of plug-filler has been removed;
forming at least one trench in the insulator using the layer of photoresist;
whereby the one or more filled plug openings and the at least one trench form the dual damascene structure.

14. The method of claim 8 further comprising:
applying a backside antireflective coating (BARC) after the portion of plug-filler has been removed;
applying a layer of photoresist above the BARC.

15. The method of claim 8 further comprising:
baking the insulator filled with plug-filling material prior to removing the portion.

16. The method of claim 15 wherein the portion of plug-filling material is removed without performing any additional processing steps after the baking.

17. A plug-filling material for use in a dual damascene structure on a semiconductor substrate, comprising:
at least fifty percent concentration of cross-linking material; and
at least twenty five percent concentration of an additive for reducing a cross-linking property of the cross-linking material so that a substantial portion of the plug-filling material can be removed, after baking, by using a reduced resist coating (RRC) solvent.

18. The plug-filling material of claim 17 wherein the plug filler includes Novolac having a molecular weight above 1,800.

19. The plug-filling material of claim 17 wherein the plug filler includes poly hydroxy styrene (PHS) having a molecular weight above 2,800.

20. The plug-filling material of claim 17 wherein the substantial portion of the plug-filling material is at least 200 Angstroms of material thickness.
